(19) United States
(12) Patent Application Publication
(10) Pub. No.: US 2002/0130725 A1
(43) Pub. Date: Sep. 19, 2002

(54) Jitter clean-up circuit for communications applications

(76) Inventor: Jung Hee Han, Tustin, CA (US)

Correspondence Address: JONES VOLENTINE, PLLC, SUITE 150, 12200 SUNRISE VALLEY DRIVE, RESTON, VA, 20191, US

(21) Appl. No.: 09/945,162

(22) Filed: Aug. 31, 2001

Related U.S. Application Data
(60) Provisional application No. 60/276,135, filed on Mar. 16, 2001.

(51) Int. Cl. H03B 1/00

(52) U.S. Cl. 331/46

(57) ABSTRACT

In accordance with an exemplary embodiment of the present invention, an optical subassembly includes a clock-jitter clean-up circuit. The clock-jitter clean-up circuit is adapted to receive reference clock signals having a plurality of reference clock frequencies, and is adapted to output a transmit reference clock signal having one of the reference clock frequencies. The transmitted reference clock frequency is substantially jitter-free.

### CROSS-REFERENCE TO RELATED APPLICATIONS

The present application claims priority under 35 U.S.C. 119 (e) from U.S. Provisional Patent Application No. 60/276,135, filed Mar. 16, 2001 and entitled “Integrated Optical Subsystem Module Including Jitter Clean-Up Circuits.” The disclosure of the above captioned provisional patent application is specifically incorporated by reference herein and for all purposes.

### FIELD OF THE INVENTION

The present invention relates generally to communications, and particularly to a jitter clean-up circuit for use in an integrated optical subsystem module.

### BACKGROUND OF THE INVENTION

There are numerous ways in which to transfer voice and data from a transmitter to a receiver. Generally, a transmitter includes clock circuitry which controls the speed at which data in transferred via a particular communications medium. The receiver also has clock circuitry which controls the speed at which the data that is received from the communications medium is processed. Usefully, the receiver's clock and transmitter's clock operate at the same frequency and are aligned in phase. However, the frequency of the transmitter clock and receiver clock may not be identical, which can result in a slight frequency mismatch. Furthermore “jitter”, which is time-shifting of the communications signal relative to the rise and fall time of the transmitter's clock signal, may be introduced into the data.

Conventionally, jitter is defined as short-term phase variations of the significant instants of a digital signal from there ideal positions in time. In the frequency domain, jitter is manifest as phase noise. The significant instant can be any convenient, easily identifiable point on the signal, such as the rising or falling edge of the pulse. This jitter may result from a variety of sources, including the communications medium itself (e.g., an optical fiber). Clock-jitter may include jitter caused by data inter-symbol interference (ISI).

It is important to control jitter in a communication system because it can degrade the performance of a transmission system. Jitter causes bit-errors by preventing the clock recovery circuit in the receiver from sampling the digital signal at an optimum instant in time. To this end, to accurately determine whether a given bit is a one or a zero, the signal should be sampled at the instant in time where the vertical eye opening on an eye diagram is at a maximum. The decision point is set by the recovered clock signal. If jitter on the data causes this point to move away from the optimized rotation, the decision margin decreases and the system bit-error rate increases. In addition, jitter can accumulate in a transmission network depending upon the jitter generation and transfer characteristics of the interconnected equipment.

Typically, communications industry standards, such as synchronous optical network (SONET) and synchronous digital hierarchy (SDH) specify the jitter requirements at the optical interface necessary to control jitter accumulation within the transmission system. For example, one specified jitter requirement is known as jitter transfer. Jitter transfer is a measure of the amount of jitter transmitted from input to output of a particular regenerator. Jitter transfer specifications help ensure that once installed in a system, equipment will not cause an unacceptable increase in jitter in any particular part of the spectrum. A cascade of similar units, each with just a small increase in jitter can result in an unacceptable jitter level. SONET/SDH specifications define allowable jitter transfer functions for various transmission rates and regenerator types.

One particular parameter that is closely related to jitter is known as the timing margin. The timing margin is the time that the data eye is valid for a device to detect a digital “one” or a digital “zero”. The timing margin is typically equal to the clock period minus a variety of parameters, including clock-jitter, which includes jitter caused by data ISI. It is useful therefore, to control jitter to improve the timing margin.

From the above discussion, it can be appreciated that jitter present in a reference clock signal should be minimized as much as possible. One way to reduce the jitter in a clock signal is with clock-jitter clean-up circuits. One type of clock-jitter clean-up circuit is a phase nulling circuit, which removes phase noise at a specific clock signal frequency. While such conventional jitter-reducing devices may be beneficial, they have drawbacks, particularly due to limited application. To this end, conventional jitter clean-up circuits are capable of reducing jitter at a particular frequency. Therefore, each clock frequency requires its own jitter clean-up circuit. As can be appreciated, this can be impractical in deployed systems. Furthermore, because these conventional clock clean-up circuits are designed for a specific frequency, they are not readily variable (i.e. adaptable to change). As such, if it is desired to change to a different clock frequency, a new clock clean-up circuit is needed.

As can be appreciated, while clock-jitter clean-up is useful, conventional implementations suffer from at least the drawbacks described above. Accordingly, what is needed, is a clock-jitter clean-up apparatus which overcomes the shortcomings of the prior art described above.

### SUMMARY OF THE INVENTION

In accordance with an exemplary embodiment of the present invention, an optical subassembly includes a clock-jitter clean-up circuit. The clock-jitter clean-up circuit is adapted to receive reference clock signals having a plurality of reference clock frequencies, and is adapted to output a transmit reference clock signal having one of the plurality of reference clock frequencies. The transmitted reference clock frequency is has low phase noise characteristics.

### BRIEF DESCRIPTION OF THE DRAWINGS

The invention is best understood from the following detailed description when read with the accompanying drawing figures. It is emphasized that the various features are not necessarily drawn to scale. In fact, the dimensions may be arbitrarily increased or decreased for clarity of discussion.

FIG. 1 is a functional block diagram of an integrated optical subsystem in accordance with an exemplary embodiment of the present invention.

FIG. 2 is a functional block diagram of a clock-jitter clean-up circuit in accordance with an exemplary embodiment of the present invention.

FIG. 3 is a functional block diagram of a clock-jitter clean-up circuit in accordance with an exemplary embodiment of the present invention.

### DETAILED DESCRIPTION

In the following detailed description, for purposes of explanation and not limitation, exemplary embodiments disclosing specific details are set forth in order to provide a thorough understanding of the present invention. However, it will be apparent to one having ordinary skill in the art having had the benefit of the present disclosure, that the present invention may be practiced in other embodiments that depart from the specific details disclosed herein. Moreover, descriptions of well-known devices, methods and materials may be omitted so as to not obscure the description of the present invention.

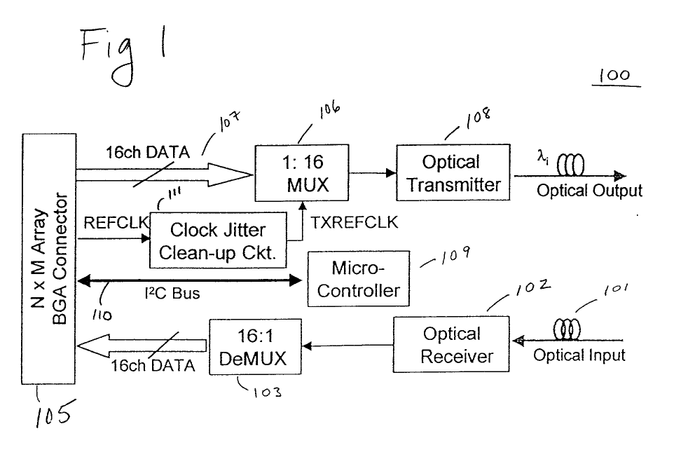

FIG. 1 shows an integrated optical subsystem 100 in accordance with an exemplary embodiment of the present invention. The integrated optical subsystem 100 may be part of a transceiver module at an end-user interface. Alternatively, the integrated optical subsystem 100 may be used as an optical repeater which detects the optical signal, and regenerates, retimes and retransmits the signal in a deployed system. Generally, the integrated optical subsystem 100 is for digital applications.

An input optical signal 101 is received at the optical receiver 102. The optical receiver 102 converts the input optical signal 101 into an electrical signal using a photodetector and a preamplifier circuit (not shown). In addition to optical-to-electrical conversion, the optical receiver 102 also recreates the input data stream and clock signal of the optical input 101. Since the received signal power can vary, the optical receiver should have some form of quantization amplifier, such as a limiting amplifier. Output from the limiting amplifier is then input to a clock and data regeneration (CDR) circuit. The CDR extracts the clock and data signals, and the clock signal is then used to trigger a decision circuit. The decision circuit then decides if a digital “one” or a digital “zero” has been received.

Output from the optical receiver 102 is input to a demultiplexer (demux) 103. The demulitplexer (e.g., a 16:1 demultiplexer) deserializes the serial data stream from the optical receiver 102 into individual electrical signals. Illustratively, in the present example, the demultiplexer 103 deserializes the serial data stream input from the optical receiver 102 into a 16-channel low-voltage differential signal (LVDS) electrical signals. Output from the demultiplexer 103 may then be input to an interface 105, which is illustratively an N×M array ball grid array (BGA). The interface 105 may be used to interface with a user interface application board.

On the transmit side, a multiplexer 106 serializes a plurality of individual channels into a serial data stream. Illustratively, the multiplexer 106 is a 16-channel multiplexer which serializes 16-channel differential LVDS electric signal 107 into a serial data stream. An optical transmitter 108 converts the serial data into an optical signal.

A microcontroller 109 may be used to monitor and control the optical transmitter 108, the optical receiver 102, the multiplexer 106 and the demultiplexer 103. Microcontroller 109 may be interfaced to the various components which it controls via a bus 110, which is in contact with interface 105. The bus 110 is illustratively a bus which complies with the I²C protocol. Finally, the integrated optical subsystem 100 further includes a clock-jitter clean-up circuit 111 in accordance with exemplary embodiments of the present invention. The clock-jitter clean-up circuit 111 is an integral element of the integrated optical subsystem 100.

The clock-jitter clean-up circuit may be used to reduce any jitter present on a clock signal (REFCLK) from a user interface application board. This ultimately may improve jitter generation performance from the serialized data output from the multiplexer 106. Moreover, a reduction in jitter may also facilitate compliance with the International Telecommunications Union (ITU) jitter requirements. As further described in further detail herein, the clock-jitter clean-up circuit 111 in accordance with the exemplary embodiments of the present invention is designed to accommodate a plurality of different reference clock frequencies. Advantageously, the clock-jitter clean-up circuit 111 of the present exemplary embodiment may be deployed in a subsystem module which includes integrated optical subsystem 100. In this way a variety of clock signal frequencies may be input to multiplexer 106 substantially jitter-free from an external clock signal (e.g. REFCLK) using only clock clean-up circuit 111. Accordingly, end-users have the option to select and change the reference clock frequency in a deployed system. Moreover, the transmit reference clock signal (TXREFCLK) has the same phase and frequency (i.e., phase and frequency locked) to the incoming reference clock signal (REFCLK), which is generally a noisy signal.

In accordance with exemplary embodiments described presently, the clock-jitter clean-up circuit may be incorporated into submodules which operate at a plurality of discrete frequencies. Alternatively, the clock-jitter clean-up circuit may be designed to be continuously tunable across a spectrum of clock frequencies. In either case, the clock-jitter clean-up circuit in accordance with an exemplary embodiment of the present invention may be used to reduce jitter in clock signals having a plurality of reference clock frequencies.

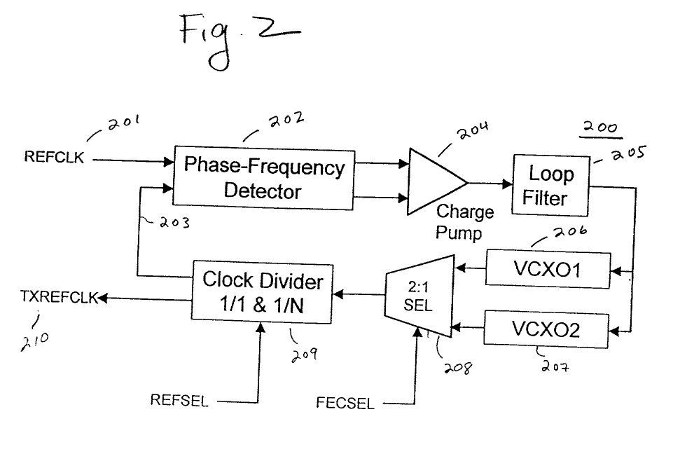

Turning to FIG. 2, a clock-jitter clean-up circuit 200 in accordance with an exemplary embodiment of the present invention is shown. Clock-jitter clean-up circuit 200 may be implemented as the clock-jitter clean-up circuit 111 shown in FIG. 1. A reference clock signal (REFCLK) 201 may be input to a phase frequency detector 202. The reference clock signal (REFCLK) 201 may be at a first fundamental frequency f₀, or an integer (N) fraction (i.e. harmonic) thereof (f₀/N). Alternatively, the reference clock frequency 201 may be a second fundamental frequency f₁, or an integer (N) fraction thereof (f₁/N) fraction thereof. A phase frequency detector 202 is useful in comparing the phase and frequency of the incoming reference clock signal 201 with a low phase noise clock signal 203, which originates illustratively from a voltage controlled oscillator (described below). A charge pump 204 and loop filter circuit 205 are useful in filtering out high frequency components of phase noise that may be present at the output of the phase frequency detector 202. The output of loop filter circuit 205 is used as the input drive voltage for first and second voltage controlled oscillators 206 and 207, respectively.

First and second voltage controlled oscillators 206 and 207 are illustratively voltage controlled crystal oscillators (VCXO). First voltage controlled oscillator 206 operates at first fundamental frequency f₀, while second voltage controlled oscillator 207 operates at second fundamental frequency f₁. For purposes of illustration, and not limitation, first voltage controlled oscillator 206 may be operating at a particular SONET frequency, while second voltage controlled oscillator 207 may be operating at a gigabit ethernet frequency, or a forward error correction (FEC) line rate. It is noted that the frequency output of respective first and second voltage controlled oscillators 206 and 207 are substantially fixed. The phase output may be changed by voltage application. This is particularly useful to ensure that the “clean-up” transmit reference clock signal (TXREFCLK) is phase-locked to the incoming reference clock signal (REFCLK) 201.

The output of first and second voltage controlled oscillators 206, 207 are input to a two-to-one selector 208 (2:1 SEL). A frequency selection signal (FECSEL) is input to the 2:1 SEL 208 to control which frequency of operation (i.e., f₀ or f₁) is output from the 2:1 selector 208. As can be appreciated by one having ordinary skill in the art, the phase frequency detector, charge pump, loop filter and one of the voltage control oscillators form a phase locked loop (PLL). As such, the 2:1 SEL having input from the FECSEL signal may be used to choose a lock frequency of the PLL. For example, if the input reference clock frequency is first fundamental frequency f₀, the output of first voltage controlled oscillator 206 would be selected by the 2:1 SEL 208. This signal would ultimately be used as the low phase noise clock signal 203. Alternatively, if the second fundamental frequency f₁, were input as the reference clock signal 201, the second voltage controlled oscillator output frequency would be selected by the 2:1 SEL, and ultimately used as the low phase noise clock circuit 203.

The output from the 2:1 SEL 208 is input to a clock divider circuit 209. The clock divider circuit provides a feedback clock (i.e., low phase noise clock signal 203) to the phase-frequency detector 202. As described above, the output of the clock divider circuit 209 has a frequency that is the same as the reference clock signal 201. Moreover, the clock divider circuit increases the number of REFCLK frequencies which may be “clean-up” by the clock jitter clean-up circuit 200. In particular, the clock-divider circuit 209 enables the fundamental frequencies (f₀, f₁) as well as integer fractions (1/N) of the fundamental frequencies (f₀, f₁) to be “cleaned-up.” To this end, as describe above, the output from the voltage controlled oscillators 206 and 207 are at the first and second fundamental frequencies f₀ and f₁, respectively. If the reference clock signal 201 is the integer fraction, (1/N) of one of the fundamental frequencies, the clock divider circuit 209 divides the frequency selected by the 2:1 selector 208 for input to the phase-frequency detector. This ensures that the frequency of the low phase-noise clock signal 203 is the same as the frequency of the reference clock signal 201; and ultimately the frequency of the output clock signal (TXREFCLK) 210.

By virtue of the clock-jitter clean-up circuit 200 of the present exemplary embodiment, the output clock signal (TXREFCLK) from the clock divider circuit is substantially phase and frequency locked to the incoming reference clock signal (REFCLK). Moreover, in accordance with the exemplary embodiment shown in FIG. 2, four reference clock signals having frequencies f₀, f₀/N, f₁, and f₁/N may be input as reference clock signal 201. These reference clock signals may include jitter, and by virtue of the clock -jitter clean-up circuit 200, the output reference clock signal (TXREFCLK) 210 is substantially free of jitter.

It is noted that the above illustrative embodiment is merely exemplary of the present invention. In fact, the number of reference clock signal frequencies may in fact be greater than four as described above. To this end, the number of reference clock signal frequencies is determined by the number of voltage controlled oscillators (e.g. VCXO 1, VCXO2) and the number of frequencies that may be generated by the clock divider circuit 209. To wit, there may be M (M=integer) voltage controlled oscillators (e.g., M voltage controlled crystal oscillators such as shown in the exemplary embodiment of FIG. 2), and N (N=integer) frequencies that my be generated by the clock divider circuit.

In this example, the two-to-one selector 208 would be replaced with a M-to-1 selector component (M:1 SEL). Moreover, the FECSEL would necessarily require to be increased to k bits (k=integer) (i.e. 2^{K} is equal to or greater than M). In this case, the total number of reference clock signal frequencies which may be input as the reference clock signal into a clock-jitter clean-up circuit in accordance with an exemplary embodiment of the present invention would equal M×N, where M is the number of voltage controlled oscillators and N is the number (integer) of frequencies that may be generated by a clock divider circuit. Finally, it is noted that the FECSEL and REFSEL signals may be digital logic signals such as low voltage TTL (LVTTL), which could be generated by a microcontroller such as microcontroller 109 in FIG. 1. This could provide suitable selectivity via the bus 110 (e.g., an I²C bus).

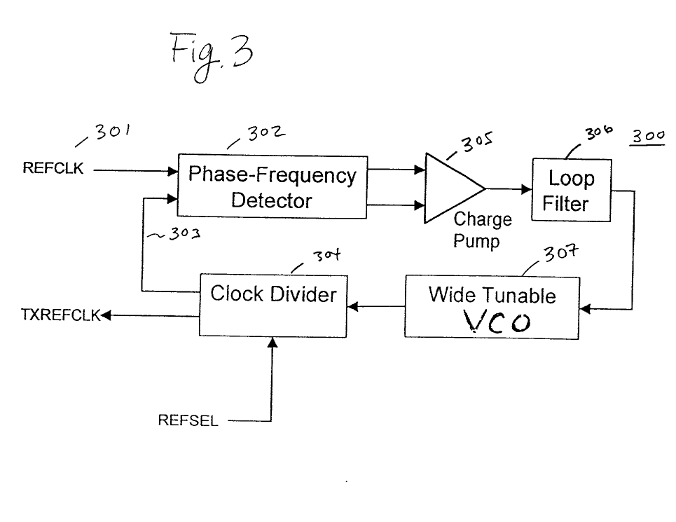

Turning to FIG. 3, a clock-jitter clean-up circuit 300 in accordance with another exemplary embodiment of the present invention is shown. The clock-jitter clean-up circuit 300 of the illustrative embodiment of the FIG. 3 is similar in operation and composition as that shown in FIG. 2, but has certain differences. These differences will be described in detail, while similarities between the two clock-jitter clean-up circuits will be foregone in the interest of brevity.

A reference clock signal 301 is input to a phase frequency detector 302 which also receives input 303 from a clock divider 304. A charge pump 305 and a loop filter 306 receive input from the phase-frequency detector 302. The output from the loop filter 306 is input to a tunable voltage controlled oscillator 307, illustratively a wide range tuneable controlled oscillator. The output from the tuneable voltage controlled oscillator 307 is input to the clock divider 304 which is controlled by a control signal (REFSEL) as shown. The clock divider outputs a clean reference clock signal (TXREFCLK) as described previously.

In accordance with the exemplary embodiment shown in FIG. 3, a wide range tunable oscillator (VCO) 307 replaces the individual discrete voltage controlled oscillators described in connection with the illustrative embodiment of FIG. 2. The clock divider circuit 304 provides a feedback clock signal 303 with the same frequency as the reference clock frequency to the phase-frequency detector. The output clock from the clock divider circuit 304 may be 1/N (where N is an integer) of the clock frequency of the voltage controlled wide tunable voltage controlled oscillator. As such, input REFCLK 301 could be continuously tuned at 1/N of oscillation frequency of wide tunable VCO 307.

Illustratively, the oscillation frequency of the tunable voltage controlled oscillator 307 could be in the range of approximately 2.4 GHz to approximately 2.7 GHz. If N=16, the frequency of the REFCLK signal 301 could be in the range of 150 MHz to 168.75 MHz. Alternatively, if N=4, the frequency of the REFCLK 301 could be in the range of 600 MHz to 675 MHz. Again, in operation, the output TXREFCLK is phase and frequency locked to the reference clock signal. Of course, TXREFCLK has been “clean-up” with a significant reduction in jitter (phase noise in the frequency domain).

The above illustrative embodiments have certain noteworthy advantages. For example, in the illustrative embodiment shown in FIG. 2, because of relatively low phase noise of the VCXO's the circuit exhibits exceptional jitter generation performance. Moreover, illustrative embodiment of FIG. 3 provides a wide tuning range of REFCLK frequencies via the wide tuneable VCO. In addition, this illustrative embodiment offers a simple configuration (e.g., does not require an FECSEL). Still other advantages will be readily apparent to one of ordinary skill in the art.

The invention having been described in detail, it will be readily apparent to one having ordinary skill in the art that the invention may be varied in a variety of ways. Such variations are not to be regarded as a departure from the scope of the invention. All such modifications as would be obvious to one of ordinary skill in the art, having had the benefit of the present disclosure, are intended to be included within the scope of the appended claims and the legal equivalents thereof.

I claim:

1. An optical subassembly, comprising:
A clock-jitter clean-up circuit which is adapted to receive reference clock signals having a plurality of reference clock frequencies, and which is adapted to output a transmit reference clock signal having one of said plurality of reference clock frequencies.

2. An optical subassembly as recited in claim 1, wherein said plurality of reference clock frequencies further comprises a discrete number of reference clock frequencies.

3. An optical subassembly as recited in claim 2, wherein said discrete number is four.

4. An optical subassembly as recited in claim 1, wherein said plurality of reference clock frequencies are in a prescribed frequency band.

5. An optical subassembly as recited in claim 1, wherein said circuit further includes a plurality of voltage controlled oscillators, and each of said voltage controlled oscillators is adapted to oscillate at a defined frequency.

6. An optical subassembly as recited in claim 5, wherein said plurality of reference clock frequencies includes each of said defined frequencies at which said voltage controlled oscillators are adapted to oscillate.

7. An optical subassembly as recited in claim 6, wherein said plurality of reference clock frequencies further includes at least one fraction of each of said defined frequencies.

8. An optical subassembly as recited in claim 1, wherein said circuit further includes a tunable voltage controlled oscillator, which is adapted to oscillate over a defined frequency range.

9. An optical subassembly as recited in claim 1, wherein said transmit reference clock signal is input to a multiplexer of the subassembly.

10. An optical subassembly as recited in claim 1, wherein said circuit further comprises a clock divider.

11. An optical subassembly as recited in claim 5, wherein said plurality of voltage-controlled oscillators is an integer, M.

12. An optical subassembly as recited in claim 11, wherein said clock-jitter clean-up circuit further includes a 1/1 clock divider and a 1/N clock divider, where N is an integer.

13. An optical subassembly as recited in claim 12, wherein said plurality of reference clock frequencies equals M×N.

14. An optical subassembly as recited in claim 1, wherein said plurality of reference clock frequencies includes a plurality of fundamental frequencies and harmonics thereof.

15. An optical subassembly as recited in claim 14, wherein said plurality of fundamental frequencies equals M and said harmonics thereof equals N, where M and N are integers.

16. An optical subassembly as recited in claim 15, wherein said circuit further comprises M voltage controlled crystal oscillators.

17. An optical subassembly as recited in claim 15, wherein said circuit further comprises a tuneable voltage controlled oscillator.

18. An optical subassembly, comprising:
a clock-jitter clean-up circuit which is adapted to receive reference clock signals of a plurality reference clock frequencies, and which is adapted to output a transmit reference clock signal, the clock-jitter clean-up circuit further comprising:
a plurality of voltage controlled oscillators, each of which is adapted to oscillate at a defined frequency.

19. An optical subassembly as recited in claim 18, wherein said plurality is an integer, M.

20. An optical subassembly as recited in claim 18, wherein said plurality of reference clock signals is equal to M×N, where M is the number of said voltage controlled oscillators and N is the number of said plurality of reference clock frequencies.

21. An optical subassembly, comprising:
a clock-jitter clean-up circuit which is adapted to receive reference clock signals of a plurality reference clock frequencies, and which is adapted to output a transmit reference clock signal, the clock-jitter clean-up circuit further comprising:
a tuneable voltage controlled oscillator which is adapted to oscillate over a defined frequency range.
